(19) United States
(12) Patent Application Publication
(10) Pub. No.: US 2025/0076402 A1
(43) Pub. Date: Mar. 6, 2025

(54) APPARATUS, SYSTEM, AND METHOD FOR MANAGEMENT A BATTERY

(71) Applicants: HYUNDAI MOTOR COMPANY, Seoul (KR); Kia Corporation, Seoul (KR)

(72) Inventor: Yo Han BAEK, Anyang-si (KR)

(73) Assignees: HYUNDAI MOTOR COMPANY, Seoul (KR); Kia Corporation, Seoul (KR)

(21) Appl. No.: 18/675,585

(22) Filed: May 28, 2024

(30) Foreign Application Priority Data
Sep. 4, 2023 (KR) 10-2023-0117173

(51) Int. Cl. G01R 31/396; B60R 16/023; B60R 16/033; G01R 31/3842; H01M 10/42; H01M 10/48

(52) U.S. Cl. CPC G01R 31/396; G01R 31/3842; H01M 10/425; H01M 10/482; B60R 16/0232; B60R 16/033; H01M 2010/4271; H01M 2010/4278; H01M 2220/20

(57) ABSTRACT

In a battery management apparatus, a system, and a method therefor, the battery management apparatus includes a communication device configured to communicate with one or more in-vehicle controllers; a voltage sensor configured for measuring a voltage value of one or more battery cells in a battery pack; a control circuit to diagnose a defect in the battery pack by use of the voltage value of the one or more battery cells measured by the voltage sensor, a battery pack voltage value across the battery pack measured by the one or more in-vehicle controllers, and a current value flowing through the battery pack; and a storage configured to store data and algorithms driven by the control circuit.

### CROSS-REFERENCE TO RELATED APPLICATION

The present application claims priority to Korean Patent Application No. 10-2023-0117173, filed on Sep. 4, 2023, the entire contents of which is incorporated herein for all purposes by this reference.

### BACKGROUND OF THE PRESENT DISCLOSURE

### Field of the Present Disclosure

The present disclosure relates to a battery management apparatus, a system, and a method therefor, and a technique for accurately diagnosing a battery cell failure.

### Description of Related Art

As a battery system such as an energy storage system (ESS) and an electric vehicle (EV) becomes widely distributed, safety issues are continuous.

If series resistance inside and outside a battery cell is greater than normal, it may cause a battery fire. Accordingly, battery defects are detected before battery use and a battery pack is constructed using only good quality products, but as a battery deteriorates or is subjected to impacts, internal and external series resistance increases.

As the internal and external series resistance of the battery increases, heat generation increases during battery charging and discharging. As heat generation increases, a heat generating area deteriorates and becomes damaged, increasing a risk of fire. Additionally, heat from a heating point is transferred to surroundings, lowering overall performance of the battery cell and accelerating deterioration due to temperature.

Furthermore, as the series resistance increases, a charging end time due to an upper limit cell voltage advances, making it impossible to fully use charging capacity of normal cells. Furthermore, as the series resistance increases, a discharging end time due to a lower limit cell voltage advances, making it impossible to fully use discharging capacity of normal cells.

Accordingly, the present series resistance is measured to diagnose battery cell defects, and in the instant case, a conventional battery cell voltage measurement system may be able to measure a terminal voltage (internal series resistance) of battery cells, but may be unable to perform voltage measurement for external series resistance increasing elements.

The information included in this Background in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a battery management apparatus, system, and method, configured for diagnosing a battery cell failure through cooperative control of a plurality of vehicle controllers.

An exemplary embodiment of the present disclosure attempts to provide a battery management apparatus, system, and method, configured for determining a voltage drop amount generated by external series resistance elements of a battery system using a battery pack voltage across a battery pack measured by a plurality of vehicle controllers, and diagnosing a battery cell failure by determining a resistance value of the series resistance elements using the voltage drop amount.

The technical objects of the present disclosure are not limited to the objects mentioned above, and other technical objects not mentioned may be clearly understood by those skilled in the art from the description of the claims.

An exemplary embodiment of the present disclosure provides a battery management apparatus including: a communication device configured to communicate with one or more in-vehicle controllers; a voltage sensor configured for measuring a voltage value of one or more battery cells in a battery pack; a control circuit to diagnose a defect in the battery pack by use of the voltage value of the one or more battery cells measured by the voltage sensor, a battery pack voltage value across the battery pack measured by the one or more in-vehicle controllers, and a current value flowing through the battery pack; and a storage communicatively connected to the control unit and configured to store data and algorithms driven by the control circuit.

In an exemplary embodiment of the present disclosure, the control circuit may be configured to determine whether at least one of a system state condition, a current magnitude condition, a time duration condition, or a combination thereof is satisfied.

In an exemplary embodiment of the present disclosure, the system state condition may include whether a vehicle is in an ignition ON state, whether the one or more in-vehicle controllers are in a normal state, and whether a relay is in an ON state.

In an exemplary embodiment of the present disclosure, the current magnitude condition may include whether a magnitude of the current exceeds a predetermined reference value.

In an exemplary embodiment of the present disclosure, the time duration condition may include a magnitude condition of the current is maintained for a predetermined time period.

In an exemplary embodiment of the present disclosure, the control circuit may be configured to determine integrity of the battery pack voltage value by determining whether the battery pack voltage value measured by the one or more in-vehicle controllers is within a predetermined error range.

In an exemplary embodiment of the present disclosure, the control circuit may be configured to determine a representative value of the battery pack voltage value by determining an average value of one or more battery pack voltage values measured by the one or more in-vehicle controllers.

In an exemplary embodiment of the present disclosure, the control circuit may be configured to determine a voltage value across an external series resistance element by use of a sum of voltage values of the one or more battery cells measured by the voltage sensor value battery pack voltage value across the battery pack measured by the one or more in-vehicle controllers.

In an exemplary embodiment of the present disclosure, the control circuit may be configured to determine a resistance value of the external series resistance element using the voltage value of the external series resistance element and the value of the current flowing through the battery pack.

In an exemplary embodiment of the present disclosure, the control circuit may be configured to diagnose a defect in the battery pack by determining whether the resistance value of the external series resistance element exceeds a predetermined threshold.

In an exemplary embodiment of the present disclosure, the control circuit may be configured to determine the resistance value of the external series resistance element a predetermined number of times, and to determine a final value among a plurality of resistance values determined the predetermined number of times.

In an exemplary embodiment of the present disclosure, the control circuit may be configured to store the resistance value of the external series resistance element in the storage along with date.

In an exemplary embodiment of the present disclosure, the external series resistance element may include at least one of contact resistance between the one or more battery cells and a bus bar joint, contact resistance between a battery module terminal and the bus bar joint, internal conduction resistance of a bus bar, contact resistance of a bus bar and joints of relays, contact resistance of relays, contact resistance of a bus bar and fuses, internal conduction resistance of fuses, contact resistance of a bus bar and plugs, contact resistance of plugs, or a combination thereof.

An exemplary embodiment of the present disclosure provides a system including: a battery management apparatus configured to diagnose a defect in a battery pack by use of a voltage value of one or more battery cells in the battery pack, a battery pack voltage value across the battery pack measured by one or more in-vehicle controllers, and a current value flowing through the battery pack; and a server configured to diagnose a defect in the one or more battery cells using the voltage value of the one or more battery cells, the battery pack voltage value and the current flowing through the battery pack, and to transmit a result of the diagnosing to the battery management apparatus.

In an exemplary embodiment of the present disclosure, the battery management apparatus may include a voltage sensor configured for measuring a voltage of the one or more battery cells in the battery pack; and a current sensor configured for measuring a current flowing in the battery pack.

In an exemplary embodiment of the present disclosure, the server may be configured to determine integrity of the battery pack voltage value by determining whether the battery pack voltage value measured by the one or more in-vehicle controllers is within a predetermined error range.

In an exemplary embodiment of the present disclosure, the server may be configured to determine a representative value of the battery pack voltage value by determining an average value of one or more battery pack voltage values measured by the one or more in-vehicle controllers.

In an exemplary embodiment of the present disclosure, the server may be configured to determine a voltage value across an external series resistance element by use of voltage values of the one or more battery cells measured by the battery management apparatus and the battery pack voltage value measured by the one or more in-vehicle controllers.

In an exemplary embodiment of the present disclosure, the server may be configured to determine a resistance value of the external series resistance element using the voltage value of the external series resistance element and a value of the current flowing through battery pack, and to diagnose a defect in the battery pack by determining whether the resistance value of the external series resistance element exceeds a predetermined threshold.

An exemplary embodiment of the present disclosure provides a battery management method including: measuring, by a control circuit, a voltage value of one or more battery cells in a battery pack; measuring, by the control circuit, a current flowing in the battery pack; receiving, by the control circuit, a battery pack voltage value across the battery pack measured by one or more in-vehicle controllers; and diagnosing, by the control circuit, a defect in the battery pack by use of a voltage value of the one or more battery cells, a battery pack voltage value across the battery pack measured by the one or more in-vehicle controllers, and a the value of the current flowing through the battery pack.

According to an exemplary embodiment of the present disclosure, it is possible to determine a voltage drop amount generated by external series resistance elements of a battery system using a battery pack voltage across a battery pack measured by a plurality of vehicle controllers, and to accurately diagnose a battery cell failure by determining a resistance value of the series resistance elements using the voltage drop amount.

According to an exemplary embodiment of the present disclosure, cost reduction is possible by obtaining a battery pack voltage measured from multiple vehicle controllers and using it to diagnose a battery cell failure without need to install a separate voltage sensor to measure a battery pack voltage.

Furthermore, various effects which may be directly or indirectly identified through the present specification may be provided.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 illustrates a block diagram showing an exemplary configuration of an entire system for battery management.

FIG. 2 illustrates a block diagram showing an exemplary configuration of a system for diagnosing a battery cell failure.

FIG. 3 illustrates a block diagram showing another exemplary configuration of a system for diagnosing a battery cell failure.

FIG. 4 illustrates a block diagram showing an exemplary configuration of a battery system.

FIG. 5 illustrates a block diagram showing an exemplary configuration of a battery management apparatus.

FIG. 6 illustrates an example view for describing internal and external series resistance of a battery system.

FIG. 7 illustrates a view for describing an example external series resistance determining method.

FIG. 8 illustrates a flowchart showing an example external series resistance determining method.

FIG. 9 illustrates a flowchart showing another example external series resistance determining method.

FIG. 10 illustrates an example computing system.

It may be understood that the appended drawings are not necessarily to scale, presenting a somewhat simplified representation of various features illustrative of the basic principles of the present disclosure. The predetermined design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, some exemplary embodiments of the present disclosure will be described in detail with reference to exemplary drawings. It should be noted that in adding reference numerals to constituent elements of each drawing, the same constituent elements include same reference numerals as possible even though they are indicated on different drawings. In describing an exemplary embodiment of the present disclosure, when it is determined that a detailed description of the well-known configuration or function associated with the exemplary embodiment of the present disclosure may obscure the gist of the present disclosure, it will be omitted.

In describing constituent elements according to an exemplary embodiment of the present disclosure, terms such as first, second, A, B, (a), and (b) may be used. These terms are only for distinguishing the constituent elements from other constituent elements, and the nature, sequences, or orders of the constituent elements are not limited by the terms. Furthermore, all terms used herein including technical scientific terms include the same meanings as those which are generally understood by those skilled in the technical field to which an exemplary embodiment of the present disclosure pertains (those skilled in the art) unless they are differently defined. Terms defined in a generally used dictionary shall be construed to have meanings matching those in the context of a related art, and shall not be construed to have idealized or excessively formal meanings unless they are clearly defined in the present specification.

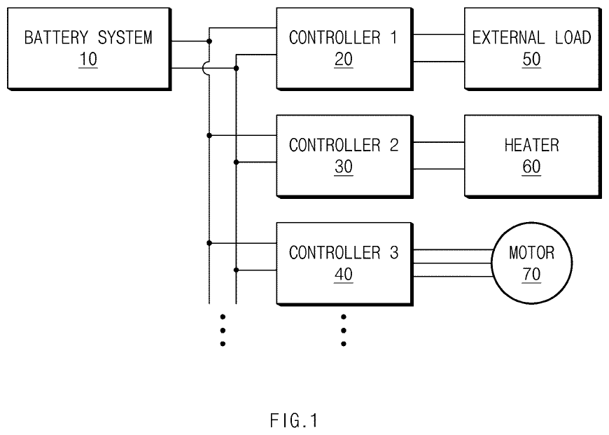

Hereinafter, various exemplary embodiments of the present disclosure will be described in detail with reference to FIG. 1 to FIG. 10.

FIG. 1 illustrates a block diagram showing an exemplary configuration of a battery system.

The battery system 10 supplies power to in-vehicle controllers 20, 30, and 40.

The in-vehicle controllers 20, 30, and 40 may supply power to an external load 50, a heater 60, a motor 70, etc. The controller 20, which is a controller that is configured to control an electric load, may be configured for controlling power supply to the external electric load 50, and the controller 30 may include a DC/DC converter and may be configured for controlling power supply to the heater 60, etc. The controller 40 may include a DC/AC converter and may be configured for controlling power supply to the motor 70, etc.

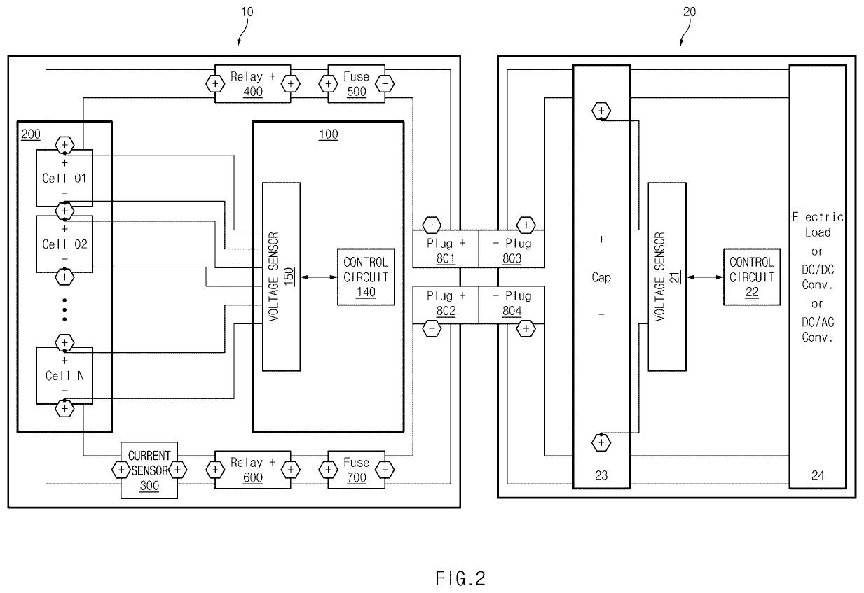

FIG. 2 illustrates a block diagram showing an exemplary configuration of a system for diagnosing a battery cell failure.

The battery system 10 according to an exemplary embodiment of the present disclosure may be implemented inside a vehicle or separately. In the instant case, the battery system 10 may be integrally formed with internal control units of the vehicle, or may be implemented as a separate hardware device to be connected to control units of the vehicle by a connection means. For example, the battery system 10 may be implemented integrally with the vehicle, may be implemented in a form which is installed or attached to the vehicle as a configuration separate from the vehicle, or a portion thereof may be implemented integrally with the vehicle, and another portion may be implemented in a form which is installed or attached to the vehicle as a configuration separate from the vehicle.

The battery system 10 may be electrically connected to the in-vehicle controller 20, and may communicate with each other for cooperative control.

The battery system 10 according to an exemplary embodiment of the present disclosure includes a battery management apparatus 100, a battery pack 200, a current sensor 300, relays 400 and 600, and fuses 500 and 700.

The battery management apparatus 100 may be configured to determine a voltage drop amount for external serial resistance factors (e.g., a bus bar, a joint, a relay joint, a fuse joint, a plug joint, etc.) through cooperation control with the in-vehicle controller 20, may be configured to determine resistance values of the external serial resistance factors using the determined voltage dropped amount, and may detect abnormal and excessive changes in external serial resistance by use of the determined external serial resistance values. To the present end, the battery management apparatus 100 may include a control circuit 140 and a voltage sensor 150.

The control circuit 140 may be configured to determine a voltage change amount due to an external series resistance element of a battery cell and determine a resistance value for the external series resistance element based on the voltage change amount by use of measurement results of a voltage of each of the battery cells Cell 01 to Cell N of the voltage sensor 150 and a battery pack voltage Vpack obtained by the controller 20 that is cooperatively configured to control the battery system 10. Next, the control circuit 140 may be configured to determine whether the resistance value of the external series resistance element is greater than a predetermined threshold, and in response to a case where the resistance value of the external series resistance element is greater than the predetermined threshold, may be configured to determine that resistance due to the external series resistance element has increased and diagnose that the battery pack is defective.

The voltage sensor 150 may measure the voltage of each of the battery cells Cell 01 to Cell N.

Furthermore, in relation to the position of the voltage sensor 150, in response to a where the voltage sensor 150 is installed at an input terminal of the relay 400, a voltage sensing circuit may be formed at all times, and thus a dark current may continuously flow, increasing energy loss of the battery system 10.

Furthermore, when the voltage sensor is installed at an input terminal of a plug 801 to measure the voltage of the battery pack, it becomes impossible to detect a change in external series resistance present at a plug contact for connecting predetermined voltage portions of different systems. Furthermore, to measure the voltage of the battery pack, a pack voltage sensor configured for measuring the voltage of the battery pack 200 must be added in addition to the voltage sensor 150 which is configured for measuring a battery cell voltage, which may increase costs.

Accordingly, in an exemplary embodiment of the present disclosure, the voltage drop amount outside the battery cell may be obtained through cooperative control with the in-vehicle controller 20 without adding a battery pack voltage sensor configured for measuring a voltage of a separate battery pack. That is, the in-vehicle controller 20 may measure a voltage at output terminals of plugs 803 and 804, i.e., a voltage across the battery pack to provide it to the battery system 10, and thus the battery management apparatus 100 may be configured to determine the voltage drop amount that occurs at contact portions between plugs 801 and 802 and the plugs 803 and 804.

The battery pack 200 includes one or more battery cells Cell 01 to Cell N connected in series.

The current sensor 300 may measure a current of the battery pack 200.

The relays 400 and 600 and the fuses 500 and 700 may transmit the voltage of the battery pack 200 to the in-vehicle controller 20 outside the battery system 10. Although FIG. 2 illustrates one in-vehicle controller 30, it may further include a plurality of controllers.

A voltage drop may occur due to generation of series resistance between contact points at opposite ends of one or more battery cells Cell 01 to Cell N, the relays 400 and 600, the fuses 500 and 700, and the current sensor 300.

Furthermore, the battery system 10 may be connected to the in-vehicle controller 20 through the plugs 801, 802, 803, and 804, and external series resistance may occur between contact points at both ends of each of the plugs 801, 802, 803, and 804, resulting in a voltage drop. An external series resistance element, which is an element that generates a voltage drop outside of the battery cells Cell 01 to Cell N., may include contact resistance of a conductor electrically connected to a battery cell terminal, internal resistance of the conductor itself, contact resistance of a contact in a switch, internal resistance of a protective device such as a fuse or a positive temperature coefficient, connector or plug contact resistance, etc.

The in-vehicle controller 20 may measure the battery pack voltage Vpack, which is a voltage outputted from the battery pack 200.

The in-vehicle controller 20 may include a voltage sensor 21, a control circuit 22, a first device 23, and a second device 24. Opposite ends of the first device 23 may be connected to the battery system 10, and the voltage sensor 21 may measure a voltage across the first device 23. The control circuit 22 may obtain a measurement result of the voltage across the first device 23 to provide the result to the battery system 10. The second device 24 may include an electrical load, a DC/DC converter, a DC/AC converter, etc. In the instant case, the voltage across the first device 23 may indicate the battery pack voltage Vpack, which is the voltage outputted from the battery system 10.

Previously, it was only possible to measure resistance of internal series resistance elements of a battery cell through the battery system 10, but it was not possible to measure resistance of external series resistance elements outside the battery cell, so a precise voltage drop amount could not be measured. Accordingly, according to an exemplary embodiment of the present disclosure, the resistance of the external series resistance elements of the battery cell may be measured through the cooperation of the in-vehicle controller 20, accurately diagnosing a defect in the battery cell.

In the instant case, the external series resistance elements, which are elements that generate a voltage drop outside a measurement point of the battery cells Cell 01 to Cell N, may include contact resistance of a battery cell and a bus bar joint, contact resistance of a battery module and a bus bar joint, continuity resistance inside a bus bar, contact resistance between a bus bar and a relay joint, resistance between contact points at opposite ends of the relays 400 and 600, contact resistance of a bus bar and the fuses 500 and 700, resistance between contact points at opposite ends of the current sensor 300, resistance between contact points at opposite ends of the fuses 500 and 700 and contact points at opposite ends of the plugs 801, 802, 803, and 804, and resistance between opposite ends of the first device 23, etc.

The in-vehicle controller 20 may include one or more controllers, and as illustrated in FIG. 1, may include various controllers for controlling power supply to in-vehicle devices (e.g., motors, heaters, electric loads, etc.).

Accordingly, according to an exemplary embodiment of the present disclosure, a defect in the battery pack 200 may be diagnosed by determining external series resistance of a battery cell using multiple control systems, and by detecting an abnormal increase in series resistance outside the battery cell monitoring a change trend of the external series resistance. The abnormal increase refers to a case where the external series resistance of a battery cell is greater than a predetermined reference value.

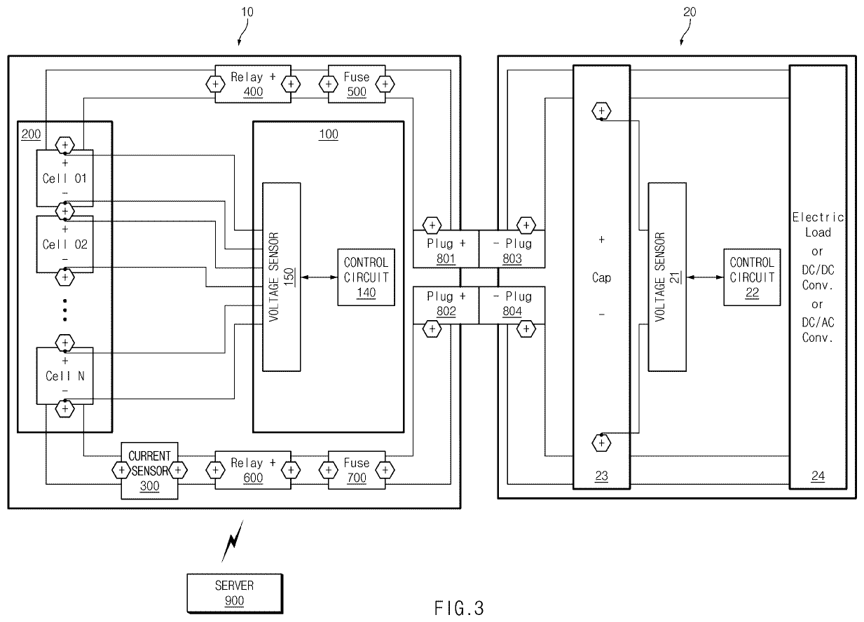

FIG. 3 illustrates a block diagram showing another exemplary configuration of a system for diagnosing a battery cell failure.

The battery system 10 according to another exemplary embodiment of the present disclosure includes the same configuration as that of the battery system 10 of FIG. 2. However, the system in FIG. 3 may further include a server 900, and the server 900 may diagnose a defect in a battery pack by determining a voltage drop amount due to a series resistance element.

The battery management apparatus 100 according to another exemplary embodiment of the present disclosure may be configured to determine a series resistance value outside the battery cell in the server 900 by transmitting voltage measurement results of one or more battery cells Cell 1 to Cell N, a battery pack current value measured by the current sensor 300, a battery pack voltage measured by the controller 20, etc. to the server 900. Next, the server 900 may compare the series resistance value outside the battery cell with a predetermined threshold, and may be configured to determine that there is a large change in the series resistance value outside the battery cell to diagnose the battery cell as defective in response to a case where the series resistance value outside the battery cell exceeds the predetermined threshold. The server 900 may transmit a diagnosis result regarding a defective state of the battery cell to the battery management apparatus 100.

In the instant case, the server 900 may store the voltage measurement results of one or more battery cells Cell1 to Celln, the battery pack current value measured by the current sensor 300, the battery pack voltage measured by the controller 20, etc. Additionally, the server 900 may store the determined series resistance value outside the battery cell. To the present end, the server 900 may include a processor and a storage.

The control circuit 22 of the server 900 may diagnose a failure of one or more battery cells by use of a voltage value of one or more battery cells received from the battery management apparatus 100, a battery pack voltage value, and a current value flowing in the battery pack, and may transmit results thereof to the battery management apparatus 100.

The control circuit 22 may be configured to determine integrity of the battery pack voltage value by determining whether the battery pack voltage value measured by one or more in-vehicle controllers is within a predetermined error range.

The control circuit 22 may be configured to determine a representative value of the battery pack voltage value by determining an average value of one or more battery pack voltage values measured by one or more in-vehicle controllers.

The control circuit 22 may be configured to determine a voltage value across the external series resistance element by use of the voltage value of one or more battery cells measured by the battery management apparatus and the battery pack voltage value measured by the one or more in-vehicle controllers.

The control circuit 22 may be configured to determine a resistance value of the external series resistance element using the voltage value of the external series resistance element and the current value flowing through the battery pack, and may diagnose a defect in the battery pack by determining whether the resistance value of the external series resistance element exceeds a predetermined threshold. That is, the control circuit 22 may diagnose the defect in the battery cell in a case where the resistance value of the external series resistance element exceeds the predetermined threshold.

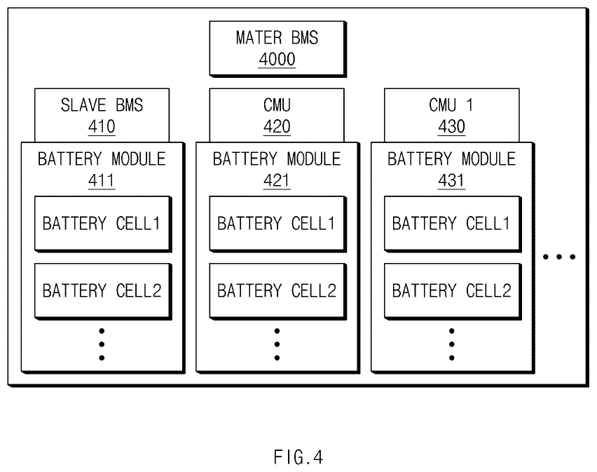

FIG. 4 illustrates a block diagram showing an exemplary configuration of a battery management apparatus 100.

The battery system includes a master battery management system (BMS) 4000, a slave BMS 410, one or more battery controllers (CMU) 420 and 430, and one or more battery modules 411, 421, and 431.

Each of the one or more battery modules 411, 421, and 431 may include one or more battery cells. The master BMS 4000 may obtain information related to the battery module 411 through the slave BMS 410.

The CMU 420 may transfer information (e.g., a measured voltage) of the battery module 421 to the master BMS 4000. Additionally, the CMU 430 may transfer information (e.g., measured voltage) of the battery module 431 to the master BMS 4000.

The battery management apparatus 100 according to an exemplary embodiment of the present disclosure may be implemented as the master BMS 4000, and may be configured to determine whether the battery cell is defective due to the series resistance by determining the external series resistance value through cooperation with the in-vehicle controller 20.

The battery management apparatus 100 may be configured to determine the resistance value of the external series resistance element using the voltage drop amount measured by the voltage sensor 21 of the in-vehicle controller 20, and may diagnose whether the battery cell is defective by use of the resistance value of the external series resistance element.

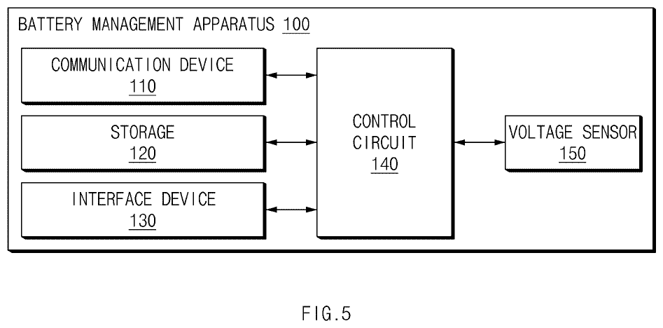

FIG. 5 illustrates a block diagram showing an exemplary configuration of a battery management apparatus.

Referring to FIG. 5, the battery management apparatus 100 may include a communication device 110, a storage 120, an interface device 130, a control circuit 140, and a voltage sensor 150. According to an exemplary embodiment of the present disclosure, the battery management apparatus 100 may be implemented as a single unit by coupling components with each other, and some components may be omitted.

The communication device 110 is a hardware device implemented with various electronic circuits to transmit and receive signals through a wireless or wired connection, and may transmit and receive information based on in-vehicle controllers (e.g., the controller 20) and in-vehicle network communication techniques. As an exemplary embodiment of the present disclosure, the in-vehicle network communication techniques may include at least one of Controller Area Network (CAN) communication, Local Interconnect Network (LIN) communication, flex-ray communication, or a combination thereof.

Furthermore, the communication device 110 may perform communication with a server 900, infrastructure, third vehicles outside the vehicle, and the like through a mobile communication technique, a wireless Internet communication, or a short range communication technique. Herein, the wireless communication technique may include at least one of wireless LAN (WLAN), Wireless Broadband (WiBro), Wi-Fi, Worldwide Interoperability for Microwave Access (WiMAX), or a combination thereof.

The mobile communication technique refers to technical standards or communication methods for mobile communication, and may include at least one of Global System for Mobile communication (GSM), Code Division Multi Access (CDMA), code division multi access 2000 (CDMA 2000), enhanced voice-data optimized or enhanced voice-data only (EV-DO), Wideband CDMA (WCDMA), High Speed Downlink Packet Access (HSDPA), High Speed Uplink Packet Access (HSUPA), Long Term Evolution (LTE), Long Term Evolution-Advanced (LTE-A), 4th generation mobile telecommunication (4G), 5th generation mobile telecommunication (5G), or a combination thereof.

The wireless Internet communication refers to a module for wireless Internet access, and may include at least one of wireless LAN (WLAN), wireless-fidelity (Wi-Fi), Wi-Fi direct, Digital Living Network Alliance (DLNA), Wireless Broadband (WiBro), Worldwide Interoperability for Microwave Access (WiMAX), High Speed Downlink Packet Access (HSDPA), High Speed Uplink Packet Access (HSUPA), Long Term Evolution (LTE), Long Term Evolution-Advanced (LTE-A), or a combination thereof.

Furthermore, the short range communication technique may include at least one of Bluetooth, ZigBee, ultra wideband (UWB), radio frequency identification (RFID), infrared data association (IrDA), Near Field Communication (NFC), wireless universal serial bus (Wireless USB), or a combination thereof.

As an exemplary embodiment of the present disclosure, the communication device 110 may communicate with the in-vehicle controller 20, the slave BMS 410, the CMUs 420 and 430, etc. to transmit and receive battery cell voltage measurement results and determined values. Furthermore, the communication device 110 may communicate with the external server 900, may transmit a voltage value measured for each of one or more battery cells to the server 900, and may receive information related to a defective battery cell among the one or more battery cells from the server 900.

The storage 120 may store data and/or algorithms required for the control circuit 140 to operate, and the like.

As an exemplary embodiment of the present disclosure, the storage 120 may store a final value of the external series resistance together with a date as a voltage measurement result of the one or more battery cells Cell 1 to Cell N measured by the voltage sensor 150, or may store the result together with a number of determinations each time the external series resistance is determined.

The storage 120 may include a storage medium of at least one type among memories of types such as a flash memory, a hard disk, a micro, a card (e.g., a secure digital (SD) card or an extreme digital (XD) card), a random access memory (RAM), a static RAM (SRAM), a read-only memory (ROM), a programmable ROM (PROM), an electrically erasable PROM (EEPROM), a magnetic memory (MRAM), a magnetic disk, and an optical disk.

The interface device 130 may include an input means for receiving a control command from a user and an output means for outputting an operation state of the apparatus 100 and results thereof. Herein, the input means may include a key button, and may include a mouse, a joystick, a jog shuttle, a stylus pen, and the like. Furthermore, the input means may include a soft key implemented on the display. As an exemplary embodiment of the present disclosure, the interface device 130 may display diagnostic information related to a defective battery cell due to an increase in external resistance, and may output a message to notify a user whether the battery pack has failed.

The interface device 130 may be implemented as a head-up display (HUD), a cluster, an audio video navigation (AVN), or a human machine interface (HM), a human machine interface (HMI).

The output device may include a display, and may also include a voice output means such as a speaker. In the instant case, in a response to a case that a touch sensor formed of a touch film, a touch sheet, or a touch pad is provided on the display, the display may operate as a touch screen, and may be implemented in a form in which an input device and an output device are integrated.

In the instant case, the display may include at least one of a liquid crystal display (LCD), a thin film transistor liquid crystal display (TFT LCD), an organic light emitting diode display (OLED display), a flexible display, a field emission display (FED), a 3D display, or any combination thereof.

The control circuit 140 may be electrically connected to the communication device 110, the storage 120, the interface device 130, and the like, may electrically control each component, and may be an electrical circuit that executes software commands, performing various data processing and determinations described below.

The control circuit 140 may be configured to process a signal transferred between components of the flight of the battery management apparatus 100 to perform overall control so that each component can perform its function normally. The control circuit 140 may be implemented in a form of hardware, software, or a combination of hardware and software. For example, the control circuit 140 may be implemented as a microprocessor, but the present disclosure is not limited thereto. For example, it may be, e.g., an electronic control unit (ECU), a micro controller unit (MCU), or other subcontrollers mounted in the vehicle.

The control circuit 140 may diagnose a defect in the battery pack 200 by use of voltage values of one or more battery cells Cell 01 to Cell N measured by the voltage sensor 150, a battery pack voltage value across the battery pack 200 measured by one or more in-vehicle controllers 20, and a current value flowing in the battery pack measured by the current sensor 300.

The control circuit 140 may be configured to determine whether at least one of a system state condition, a current magnitude condition, a time duration condition, or a combination thereof is satisfied.

The system state condition may include whether the vehicle is in an ignition ON state, whether one or more in-vehicle controllers 20 are in a normal state, and whether the relays 400 and 600 are in an ON state, and the current magnitude condition may include whether a current magnitude exceeds a predetermined reference value. Additionally, the time duration condition may include whether the current magnitude condition is maintained for a predetermined time period.

The control circuit 140 may be configured to determine integrity of the battery pack voltage value by determining whether the battery pack voltage value measured by one or more in-vehicle controllers is within a predetermined error range.

The control circuit 140 may be configured to determine a representative value of the battery pack voltage value by determining an average value of one or more battery pack voltage values measured by one or more in-vehicle controller 20.

The control circuit 140 may be configured to determine a voltage value across the external series resistance element by use of the voltage value of one or more battery cells measured by the voltage sensor 150 and the battery pack voltage value across the battery pack measured by the one or more in-vehicle controllers.

The external series resistance element may include at least one of contact resistance between one or more battery cells Cell 01 to Cell N and the bus bar joint, contact resistance between a battery module terminal and a bus bar joint, internal conduction resistance of a bus bar, contact resistance of a bus bar and joints of the relays 400 and 600, contact resistance of the relays 400 and 600, contact resistance of a bus bar and the fuses 500 and 700, internal conduction resistance of the fuses 500 and 700, contact resistance of a bus bar and the plugs 801, 802, 803, and 804, contact resistance of the plugs 801, 802, 803, and 804, or a combination thereof.

The control circuit 140 may be configured to determine the resistance value of the external series resistance element using the voltage value of the external series resistance element and the current value flowing through the battery pack 200.

The control circuit 140 may diagnose a defect in the battery pack by determining whether the resistance value of the external series resistance element exceeds a predetermined threshold.

The control circuit 140 may be configured to determine the resistance value for the external series resistance element a predetermined number of times, and may be configured to determine a final value among a plurality of resistance values determined the predetermined number of times.

Additionally, the control circuit 140 may store the resistance value for the external series resistance element in the storage 120 along with a date.

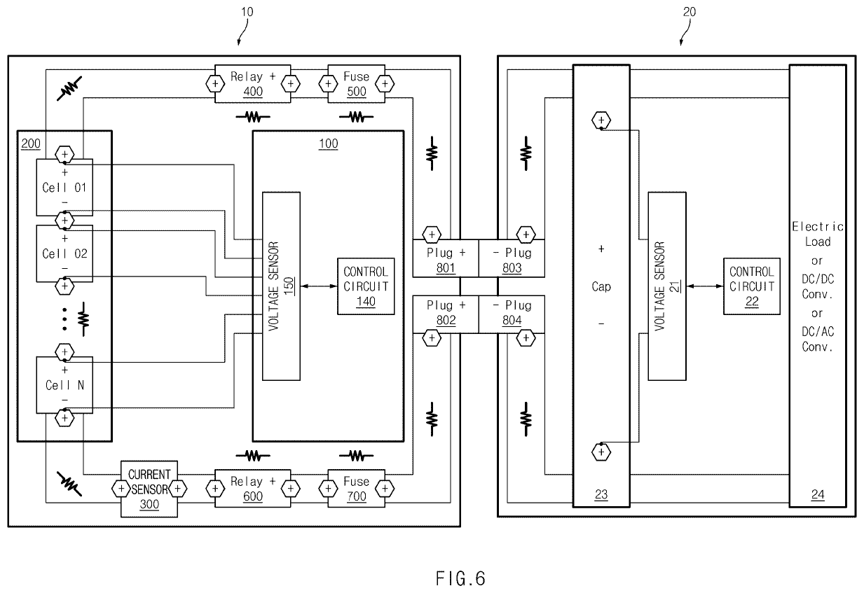

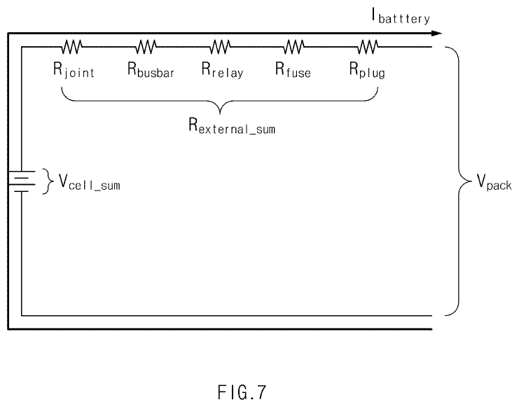

FIG. 6 illustrates an example view for describing external series resistance of a battery cell, and FIG. 7 illustrates a view for describing an example external series resistance determining method of a battery cell.

The battery management apparatus 100 measures the cell voltage of the battery cells Cell 01 to Cell N through the voltage sensor 150. In the instant case, the battery cell voltage refers to a voltage measured at each terminal of the battery cells Cell 01 to Cell N. In the instant case, the measured battery cell voltage does not include a voltage for elements other than opposite terminals of the battery cell.

The in-vehicle controller 20 measures a voltage of the battery pack 200. In the instant case, the voltage of the battery pack 200 may refer to a terminal voltage of the battery pack 200, and it may include voltage drop elements on a path, such as opposite terminals of the battery cell, bus bars, connectors, the relays 400 and 600, the fuses 500 and 700, and the plugs 801, 802, 803, and 804.

The voltage of the battery pack 200 may include a sum of voltages of all the battery cells Cell 01 to Cell N, a sum of joint voltages, a sum of bus bar voltages, a sum of relay voltages, a sum of fuse voltages, and a sum of plug voltages.

The sum of the joint voltages may include a voltage between the battery cell 01 and the relay 400, a voltage between battery cell N and the current sensor 300, etc.

The sum of the bus bar voltages, which is a sum of the voltages of the buses connected between each component, may include a voltage of a bus between the fuse 500 and the plug 801, a voltage of a bus between the fuse 600 and the plug 802, etc.

The sum of the relay voltages may include a sum of the voltages across each of the relays 400 and 600, the sum of the fuse voltages may include a sum of voltages across each of the fuses 500 and 700, and the sum of the plug voltages may include a sum of voltages across the plugs 801 and 803 and voltages across the plugs 802 and 804.

$${V}_{p a c k} = {V}_{cell\_sum} + {V}_{external\_sum} \qquad ( Equation 1 )$$

$${V}_{p a c k} = {V}_{cell\_sum} + {V}_{joint\_sum} + {V}_{busbar\_sum} + {V}_{relay\_sum} + {V}_{fuse\_sum} + {V}_{plug\_sum} \qquad ( Equation 2 )$$

$${V}_{p a c k} = {V}_{cell\_sum} + ( {R}_{j o i n t} + {R}_{b u s b a r} + {R}_{relay} + {R}_{fuse} + {R}_{plug} ) \times {I}_{battery} \qquad ( Equation 3 )$$

$${V}_{p a c k} = {V}_{cell\_sum} + {R}_{external\_sum} \times {I}_{battery} \qquad ( Equation 4 )$$

V_{pack} indicates the voltage of the battery pack 200, and V_{cell_sum} indicates the sum of the voltages of all the battery cells Cell 01 to Cell N. V_{external_sum} indicates a sum of voltages other than that of all the battery cells.

That is, the sum V_{external_sum} of the voltages other than the battery cells may include a sum V_{joint_sum} of the joint voltages, a sum V_{busbar_sum} of the bus bar voltages, a sum V_{relay_sum} of the relay voltages, a sum V_{fuse_sum} of voltages, and a sum V_{plug_sum} of the plug voltages as illustrated in FIG. 6. Accordingly, as shown in Equation 2, V_{external_sum} may be expressed as the sum V_{joint_sum} of the joint voltages, the sum V_{busbar_sum} of the bus bar voltages, the sum V_{relay_sum} of the relay voltages, the sum V_{fuse_sum} of voltages, and the sum V_{plug_sum} of the plug voltages.

As shown in Equation 3, the sum V_{external_sum} of the voltages other than the battery cells may be expressed as a resistance value and a current value.

That is, the sum V_{external_sum} of the voltages other than the battery cells may be expressed as a product of a sum R_{external_sum} of external series resistance and a current value I_{battery} of the entire battery pack. As illustrated in FIG. 7, the sum R_{extemal_sum} of the external series resistance may include a sum Rⱼₒᵢₙₜ of joint resistance, a sum Rbusbar of bus bar resistance, a sum R_{relay} of relay resistance, a sum R_{fuse} of fuse resistance, and a sum R_{plug} of plug resistance. The battery current I_{batttery} indicates a current value of the battery pack 200 measured by the current sensor 300.

Accordingly, as shown in Equation 4, the battery pack voltage V_{pack} may be determined as a sum of the sum R_{external_sum} of the external series resistance multiplied by the entire current value I_{batttery} and a sum V_{cell_sum} of voltages of all the battery cells Cell 01 to Cell N.

Equation 4 may be summarized in terms of the sum R_{external_sum} of the external series resistance as Equation 5.

$${R}_{external\_sum} = ( {V}_{p a c k} - {V}_{cell\_sum} ) / {I}_{battery} \qquad ( Equation 5 )$$

FIG. 6 and FIG. 7 show an example in which the battery system 10 is configured to determine the sum of external series resistance using one controller 20, but the present disclosure is not limited thereto, and the sum of the external series resistance may be determined using two or more controllers.

In response to using two or more controllers, the battery pack voltage may be determined to determine the sum of external series resistance by determining an average value of a plurality of measurements of the remaining controllers Vpack__{Controller1} and Vpack__{Controller2}, excluding the sum V_{cell_sum} of the battery cell voltages.

$${V}_{p a c k} = {V}_{cell\_sum} + ( {V}_{pack\_controller 1} + {V}_{pack\_controller 2} ) / 2 \qquad ( Equation 6 )$$

$${V}_{p a c k} = {V}_{cell\_sum} + ( {V}_{pack\_controller 1} + {V}_{pack\_controller 2} + {V}_{pack\_controller 3} ) / 3 \qquad ( Equation 7 )$$

Equation 6 includes an example equation for determining the battery pack voltage in response to a case where there are two controllers that cooperatively control the battery system 10, and Equation 7 includes an example equation for determining the battery pack voltage in response to a case where there are three controllers that cooperatively control the battery system 10.

For example, in response to a case where there are two controllers, the battery management apparatus 100 may be configured to determine a final battery pack voltage by adding up battery pack voltages measured by each of the controllers and dividing them by 2. Furthermore, in response to a case where there are three controllers, the battery management apparatus 100 may be configured to determine a final battery pack voltage by adding up battery pack voltages measured by each of the controllers and dividing them by 3.

In the instant case, a value obtained by the controller 20 measuring a voltage across the first device 23 including opposite ends that are connected to the plugs 803 and 804 is equal to the voltage V_{exteral_sum} other than all the battery cells.

However, in response to a case where there are two or more controllers, a process is required to check integrity of the battery pack voltage (voltage other than the battery cell) obtained by each of the controllers.

It is necessary to check whether the voltage is measured correctly using voltage measurements of multiple controllers. The battery system 10 may reduce a risk of misdiagnosis or overdiagnosis of battery cell failures by determining the external series resistance value using a battery pack voltage that performed such integrity check, increasing accuracy of detecting defective battery cells.

The battery management apparatus 100 compares the measured battery pack voltages Vpack__{controller1}, Vpack__{controller2}, . . . of the remaining controllers (controller 1, controller 2,) excluding the sum V_{cell_sum} of the battery cell voltages to be diagnosed, to check whether the error is within ±2%. For example, in response to a case where there are two controllers that cooperatively control battery 10, as shown in Equation 8, it may be seen that whether the battery pack voltages measured by the two controllers are within an error range. In response to a case where there are three controllers, as shown in Equation 9, it may be confirmed whether the battery pack voltages measured by the three controllers are within an error range.

$$98 \% < ( {V}_{pack\_controller 1} / {V}_{pack\_controller 2} ) < 102 \% \qquad ( Equation 8 )$$

$$( 98 \% < ( {V}_{pack\_controller 1} / {V}_{pack\_controller 2} ) < 102 \% ) \qquad ( Equation 9 )$$

$$\& ( 98 \% < ( {V}_{pack\_controller 2} / {V}_{pack\_controller 3} ) < 102 \% )$$

Accordingly, according to an exemplary embodiment of the present disclosure, an error range of the battery pack voltage measured by each controller may be determined, and in response to a case where the battery pack voltage measured by each controller is within a predetermined error range, the external series resistance may be determined using a battery pack voltage with certified integrity by determining that the battery pack voltage measured by each controller is correct information.

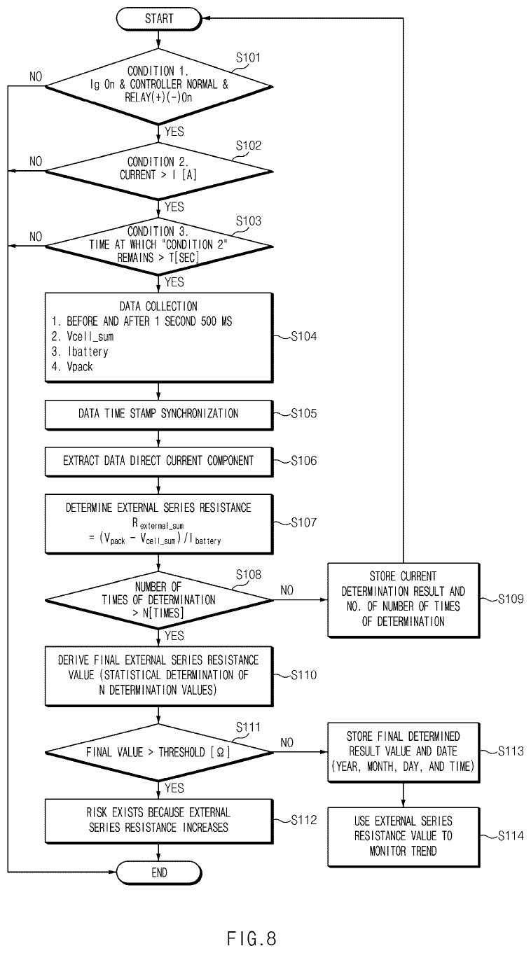

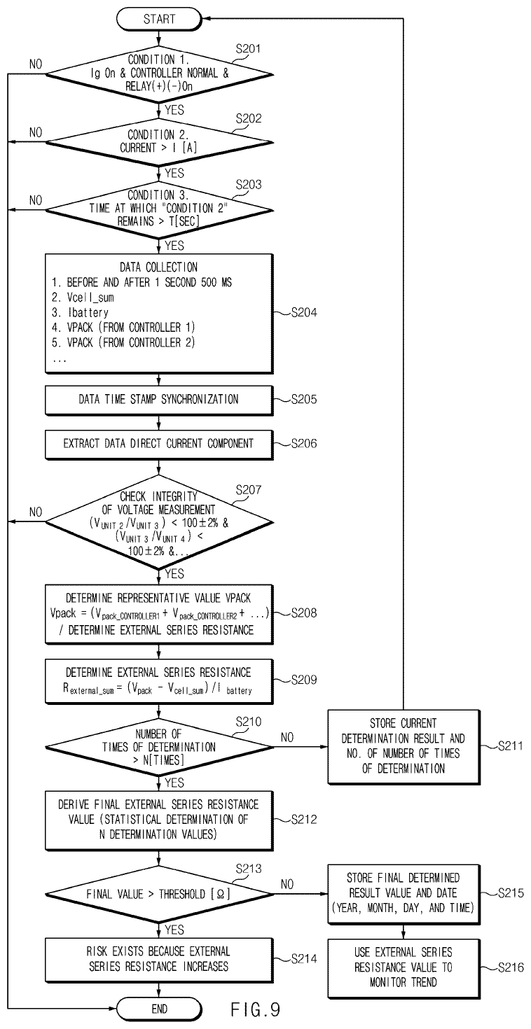

Hereinafter, an external series resistance detection method according to an exemplary embodiment of the present disclosure will be described with reference to FIG. 8. FIG. 8 illustrates a flowchart showing an example external series resistance determining method, and FIG. 9 illustrates a flowchart showing another example external series resistance determining method.

Hereinafter, it is assumed that the battery management apparatus 100 of FIG. 1 performs the processes of FIG. 8 and FIG. 9. Furthermore, in the description of FIG. 8 and FIG. 9, operations referred to as being performed by a device may be understood as being controlled by the control circuit 140 of the battery management apparatus 100. In following exemplary embodiments of the present disclosure, operations of steps S101 to S114 may be performed sequentially, but are not necessarily performed sequentially. For example, an order of each operation may be changed, and at least two operations may be performed in parallel.

Referring to FIG. 8, the battery management apparatus 100 is configured to determine whether Condition 1 is satisfied (S101).

Condition 1 includes whether the vehicle is in an ignition ON state, whether the controller 20 is in a normal state, and whether the relays 400 and 600 are in an ON state. That is, the vehicle is in the ignition ON state, self-diagnosis results of each controller involved in diagnosing a battery cell defect are all normal, and contact points of positive and negative relays (switches) for supplying a voltage and a current of the battery system 10 to the outside may be short-circuited.

In response to a case where Condition 1 is satisfied, the battery management apparatus 100 is configured to determine whether Condition 2 is satisfied (S102).

Condition 2 may include a condition for determining whether the current of the battery pack is greater than a predetermined reference value i.

As a current increases, a voltage drop occurring in series resistance increases, and as the voltage drop increases, a measurement error of the voltage sensor 150 tends to decrease. Accordingly, as a magnitude of a current increases, accurate voltage measurement becomes possible, and thus the above logic continues to be performed in response to a case where the magnitude of the current is greater than a predetermined reference value.

FIG. 8 illustrates an example where the current exceeds the reference value, and by setting a current magnitude section, the above logic may be continued to be performed in response to the battery pack current satisfying the current magnitude section. That is, as voltage measurement is accurate, accuracy of a determination result thereof may be improved, and a measurement error of the current sensor 300 may be determined based on the current magnitude section in which it is small.

For example, in response to a case where a current sensor with a sensor rating current Irate sensor of 100 A is being used, as the current magnitude is close to 100 A, a current value may be measured with higher accuracy. For example, a current magnitude condition to be used to diagnose the current I_{battery} flowing in the battery pack 200 may be determined as follows: I_{rate_sensor}×0.95[A]<I_{battery}[A]<I_{rate_sensor}×1.05[A] in response to the high current sensor accuracy range of 95 to 105% of the rated current.

Next, the battery management apparatus 100 is configured to determine whether Condition 3 is satisfied in response to a case both Condition 1 and Condition 2 are satisfied (S103).

Condition 3 may include a case where a time for which the current magnitude in Condition 2 remains greater than the predetermined reference value i is greater than a predetermined time period t.

That is, sensor measurement accuracy is higher at a time at which a voltage and current state in the battery system is static (or steady state) than at a time at which it is dynamic (transient state), the battery management apparatus 100 is limited to using current and voltage values measured in a section where a static state persists. The data duration condition to be used for diagnosis is Δt>1 [sec]. Herein, Δt indicates a time for which the condition satisfying the current magnitude condition is maintained (t_{Save Current Measurement Exit}−t_{Start saving current measurements}).

The battery management apparatus 100 collects data from controllers for cooperative control (S104). That is, the battery management apparatus 100 may collect data at 500 ms around t seconds. Furthermore, the battery management apparatus 100 collects a sum Vcell_sum of battery cell voltages from voltage sensor 150, and collects a current I_{battery} flowing in the battery pack from the current sensor 300. Additionally, the battery management apparatus 100 collects the battery pack voltage Vpack from the controller 20.

The battery management apparatus 100 is configured to perform data time stamp synchronization (S105). That is, the battery management apparatus 100 may synchronize and store information received from each controller.

The battery management apparatus 100 extracts a data direct current component from the synchronized information (S106).

The battery management apparatus 100 is configured to determine the external series resistance using the data direct current component (S107). In the instant case, the battery management apparatus 100 may secure the battery cell voltage sum V_{cell_sum} and the battery pack current value I_{battery} by use of a good quality battery system, and may secure the battery pack voltage V_{pack} from the controller 20 to determine the external series resistance value R_{external_sum} as shown in Equation 5.

The battery management apparatus 100 is configured to determine whether a number of times the external series resistance value has been determined exceeds a predetermined number (S108). The battery management apparatus 100 may be configured to determine the external series resistance value a predetermined number of times, and may increase accuracy of a determination value by use of an average value of determination values.

In response to a case where the number of times the external series resistance value has been determined does not exceed the predetermined number, the battery management apparatus 100 may store a current determination result and a No. of a number of times of the determination in the storage 120 (S109), and may return to step S101 and repeat steps S101 to S108.

In response to a case where the number of times the external series resistance value has been determined does not exceed the predetermined number, the battery management apparatus 100 may derive a final external series resistance value using the external series resistance value determined a predetermined number of times (S110). In the instant case, the battery management apparatus 100 may derive an average value of external series resistance values determined the predetermined number of times as the final external series resistance value.

The battery management apparatus 100 is configured to determine whether the final external series resistance value exceeds a predetermined threshold (S111).

In response to a case where the final external series resistance value exceeds the predetermined threshold, the battery management apparatus 100 is configured to determine that a risk exists because the external series resistance increases (S112). That is, in response to the case where the final external series resistance value exceeds the predetermined threshold, the battery management apparatus 100 may be configured to determine that a battery cell defect has occurred due to an increase in external series resistance.

In the instant case, the threshold may be determined in advance by experimental values. That is, the battery management apparatus 100 may be configured to determine the threshold in consideration of a characteristic that resistance changes according to the exterior and internal environmental temperatures of the vehicle. Additionally, the battery management apparatus 100 may define a normal range of a resistance value for each temperature condition. In the instant case, the battery management apparatus 100 may set a range of a maximum resistance value for each defined temperature condition as a threshold point, and may use a maximum value regardless of a temperature of a detection time point of external series resistance abnormality as the threshold point.

Additionally, the battery management apparatus 100 may select an appropriate normal range according to a temperature condition of the detection time point of the external series resistance abnormality to use it the threshold point.

Meanwhile, in step S111, in response to a case where the final external series resistance value does not exceed the predetermined threshold, the battery management apparatus 100 may store the final determined external series resistance value together with a date (year, month, day, and time) in the storage 120 (S113).

The battery management apparatus 100 may use the stored external series resistance value to monitor a change in external series resistance (S114).

The battery management apparatus 100 may immediately diagnose a defective battery cell in response to a case where a magnitude of the external series resistance rapidly increases and reaches a level where an event occurs within a short time period.

Furthermore, in response to a case where the magnitude of the external series resistance gradually increases, and an increasing trend of the magnitude of the external series resistance is expected to exceed the threshold in the future, the battery management apparatus 100 may suggest and guide the user for a detailed examination.

FIG. 9 illustrates a process for determining an external series resistance value in response to a case where there are two or more controllers that cooperatively control the battery system 10.

Referring to FIG. 9, steps S201 to S206 are the same as steps S101 to S106 of FIG. 8, so detailed descriptions thereof will be omitted.

After extracting the data direct current component, the battery management apparatus 100 checks integrity of the battery pack voltage measured by a plurality of controllers (S207). In the instant case, the battery management apparatus 100 may check integrity of a plurality of battery pack voltages as shown in Equation 9 described above.

In response to a case where it is determined that there is the integrity of the battery pack voltages, that is, multiple battery pack voltages are correct information, the battery management apparatus 100 is configured to determine a representative battery pack voltage value among the battery pack voltages measured by the controllers (S208). In the instant case, the battery management apparatus 100 may be configured to determine the representative battery pack voltage by dividing the sum of the battery pack voltages measured by the controllers by a quantity of the controllers, as shown in Equation 7.

The battery management apparatus 100 is configured to determine the external series resistance by use of the representative battery pack voltage (S209).

Hereinafter, steps S210 to S216 are the same as S108 to S114 of FIG. 8, and thus a detailed description will be omitted.

Accordingly, according to an exemplary embodiment of the present disclosure, a voltage sensing current flows in response to conditions that high voltage portions connection plugs 801, 802, 803, and 804) of the two systems 10 and 20 are connected and the relays 400 and 600 are all closed are satisfied,

In a state where the high voltage portions are not connected and the relay is open, the voltage sensing current stops flowing, and thus continuous energy loss may be prevented, and as a result, the energy efficiency of the system may be increased.

Furthermore, according to an exemplary embodiment of the present disclosure, the external series resistance is determined by detecting changes in the external series resistance occurring at contact portions of the connection plugs 801, 802, 803, and 804 and determining a voltage drop amount due to the external series resistance. Accordingly, an external serial determination result also includes resistance components between plugs, allowing for more accurate diagnosis of battery cell defects.

Furthermore, according to an exemplary embodiment of the present disclosure, there is no need to install an additional battery pack voltage sensor by measuring the battery pack voltage through in-vehicle controllers, and thus costs may be reduced, including a material cost of a pack voltage sensor, an installation cost of a pack voltage sensing wire, and a basic software development cost for pack voltage sensor interface.

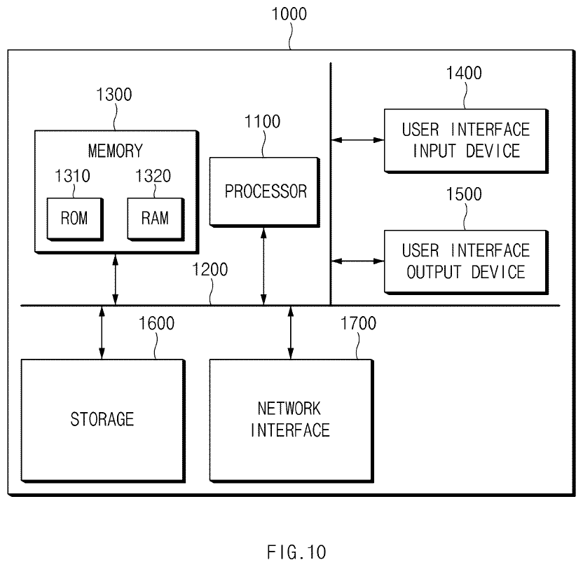

FIG. 10 illustrates an example computing system.

Referring to FIG. 10, the computing system 1000 includes at least one processor 1100 connected through a bus 1200, a memory 1300, a user interface input device 1400, a user interface output device 1500, and a storage 1600, and a network interface 1700.

The processor 1100 may be a central processing unit (CPU) or a semiconductor device that is configured to perform processing on commands stored in the memory 1300 and/or the storage 1600. The memory 1300 and the storage 1600 may include various types of volatile or nonvolatile storage media. For example, the memory 1300 may include a read only memory (ROM) 1310 and a random access memory (RAM) 1320.

Accordingly, steps of a method or algorithm described in connection with the exemplary embodiments included herein may be directly implemented by hardware, a software module, or a combination of the two, executed by the processor 1100. The software module may reside in a storage medium (i.e., the memory 1300 and/or the storage 1600) such as a RAM memory, a flash memory, a ROM memory, an EPROM memory, an EEPROM memory, a register, a hard disk, a removable disk, and a CD-ROM.

An exemplary storage medium is coupled to the processor 1100, which can read information from and write information to the storage medium. Alternatively, the storage medium may be integrated with the processor 1100. The processor and the storage medium may reside within an application specific integrated circuit (ASIC). The ASIC may reside within a user terminal. Alternatively, the processor and the storage medium may reside as separate components within the user terminal.

The above description is merely illustrative of the technical idea of the present disclosure, and those skilled in the art to which the present disclosure pertains may make various modifications and variations without departing from the essential characteristics of the present disclosure.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Furthermore, the terms such as “unit”, “module”, etc. included in the specification mean units for processing at least one function or operation, which may be implemented by hardware, software, or a combination thereof.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In the present specification, unless stated otherwise, a singular expression includes a plural expression unless the context clearly indicates otherwise.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A battery management apparatus comprising:
a communication device configured to communicate with one or more in-vehicle controllers;
a voltage sensor configured for measuring a voltage value of one or more battery cells in a battery pack;
a control circuit configured to diagnose a defect in the battery pack by use of the voltage value of the one or more battery cells measured by the voltage sensor, a battery pack voltage value across the battery pack measured by the one or more in-vehicle controllers, and a value of a current flowing through the battery pack; and
a storage communicatively connected to the control unit and configured to store data and algorithms driven by the control circuit.

2. The battery management apparatus of claim 1, wherein the control circuit is further configured to determine whether at least one of a system state condition, a current magnitude condition, a time duration condition, or a combination thereof is satisfied.

3. The battery management apparatus of claim 2, wherein the system state condition includes whether a vehicle is in an ignition ON state, whether the one or more in-vehicle controllers are in a normal state, and whether a relay is in an ON state.

4. The battery management apparatus of claim 2, wherein the current magnitude condition includes whether a magnitude of the current exceeds a predetermined reference value.

5. The battery management apparatus of claim 4, wherein the time duration condition includes whether a magnitude condition of the current is maintained for a predetermined time period.

6. The battery management apparatus of claim 1, wherein the control circuit is further configured to determine integrity of the battery pack voltage value by determining whether the battery pack voltage value measured by the one or more in-vehicle controllers is within a predetermined error range.

7. The battery management apparatus of claim 1, wherein the control circuit is further configured to determine a representative value of the battery pack voltage value by determining an average value of one or more battery pack voltage values measured by the one or more in-vehicle controllers.

8. The battery management apparatus of claim 1, wherein the control circuit is further configured to determine a voltage value across an external series resistance element by use of a sum of voltage values of the one or more battery cells measured by the voltage sensor and the battery pack voltage value across the battery pack measured by the one or more in-vehicle controllers.

9. The battery management apparatus of claim 8, wherein the control circuit is further configured to determine a resistance value of the external series resistance element using the voltage value of the external series resistance element and the value of the current flowing through the battery pack.

10. The battery management apparatus of claim 9, wherein the control circuit is further configured to diagnose a defect in the battery pack by determining whether the resistance value of the external series resistance element exceeds a predetermined threshold.

11. The battery management apparatus of claim 9, wherein the control circuit is further configured for:
determining the resistance value of the external series resistance element a predetermined number of times; and
determining a final value among a plurality of resistance values determined the predetermined number of times.

12. The battery management apparatus of claim 9, wherein the control circuit is further configured to store the resistance value of the external series resistance element in the storage along with date.

13. The battery management apparatus of claim 8, wherein the external series resistance element includes at least one of contact resistance between the one or more battery cells and a bus bar joint, contact resistance between a battery module terminal and the bus bar joint, internal conduction resistance of a bus bar, contact resistance of the bus bar and joints of relays, contact resistance of the relays, contact resistance of the bus bar and fuses, internal conduction resistance of the fuses, contact resistance of the bus bar and plugs, contact resistance of the plugs, or a combination thereof.

14. A system comprising:
a battery management apparatus configured to diagnose a defect in a battery pack by use of a voltage value of one or more battery cells in the battery pack, a battery pack voltage value across the battery pack measured by one or more in-vehicle controllers, and a current flowing through the battery pack; and
a server configured to diagnose a defect in the one or more battery cells using the voltage value of the one or more battery cells, the battery pack voltage value and the current flowing through the battery pack, and to transmit a result of the diagnosing to the battery management apparatus.

15. The system of claim 14, wherein the battery management apparatus includes:
a voltage sensor configured for measuring the voltage value of the one or more battery cells in the battery pack; and
a current sensor configured for measuring the current flowing in the battery pack.

16. The system of claim 14, wherein the server is further configured to determine integrity of the battery pack voltage value by determining whether the battery pack voltage value measured by the one or more in-vehicle controllers is within a predetermined error range.

17. The system of claim 14, wherein the server is further configured to determine a representative value of the battery pack voltage value by determining an average value of one or more battery pack voltage values measured by the one or more in-vehicle controllers.

18. The system of claim 14, wherein the server is further configured to determine a voltage value across an external series resistance element by use of voltage values of the one or more battery cells measured by the battery management apparatus and the battery pack voltage value measured by the one or more in-vehicle controllers.

19. The system of claim 18, wherein the server is further configured for:
determining a resistance value of the external series resistance element using the voltage value of the external series resistance element and a value of the current flowing through battery pack, and
diagnosing a defect in the battery pack by determining whether the resistance value of the external series resistance element exceeds a predetermined threshold.

20. A battery management method comprising:
measuring, by a control circuit, a voltage value of one or more battery cells in a battery pack;
measuring, by the control circuit, a current flowing in the battery pack;
receiving, by the control circuit, a battery pack voltage value across the battery pack measured by one or more in-vehicle controllers; and
diagnosing, by the control circuit, a defect in the battery pack by use of the voltage value of the one or more battery cells, the battery pack voltage value across the battery pack measured by the one or more in-vehicle controllers, and a value of the current flowing through the battery pack.
